(19) United States
(12) Patent Application Publication
(10) Pub. No.: US 2024/0055551 A1
(43) Pub. Date: Feb. 15, 2024

(54) LIGHT-EMITTING DEVICE

(71) Applicant: Sharp Display Technology Corporation, Kameyama City, Mie (JP)

(72) Inventors: Masayuki KANEHIRO, Kameyama City, Mie (JP); Youhei NAKANISHI, Kameyama City, Mie (JP); Shota OKAMOTO, Kameyama City, Mie (JP)

(21) Appl. No.: 18/278,480

(22) PCT Filed: Apr. 14, 2021
(86) PCT No.: PCT/JP2021/015383

§ 371 Date: Aug. 23, 2023

(51) Int. Cl. H01L 33/06; H01L 33/62

(52) U.S. Cl. CPC H01L 33/06; H01L 33/62; H01L 2933/0016

(57) ABSTRACT

A light-emitting device includes a bank provided with an opening including an opening sidewall that is inclined, a lower layer electrode provided with an inclined face and formed on the bank, closing the opening, a upper layer electrode provided with an inclined face and formed above the second electrode, and an EL layer provided with an inclined face and formed between the lower layer electrode and the upper layer electrode, adjacently to the lower layer electrode and the upper layer electrode. The light-emitting device further includes a first refractive index layer having a refractive index higher than 1.7, and a second refractive index layer having a refractive index lower than the refractive index of the first refractive index layer. The first and second refractive index layers are formed in this order on the upper layer electrode at a through-hole.

### TECHNICAL FIELD

The disclosure relates to a self-luminous light-emitting device.

### BACKGROUND ART

Conventionally, a display device, for example, which is a kind of self-luminous light-emitting device, is generally manufactured as follows. First, a substrate is prepared, and a lower layer electrode is formed on the substrate on a subpixel-by-subpixel basis. Next, a bank is formed, covering an edge of each lower layer electrode. Next, an EL layer including a light-emitting layer is formed. Note that at least the light-emitting layer of the EL layer is patterned on a subpixel-by-subpixel basis. Subsequently, an upper layer electrode is formed as a common layer common to all subpixels.

In such a self-luminous light-emitting device, light emission occurs in a thin light-emitting layer interior, making total reflection likely to occur at an interface between the above-described compound layer electrode, including the light-emitting layer, and the upper layer electrode. The totally reflected light propagates in the EL layer interior and exits as a parallel component in a direction (in-plane direction) parallel to the interface between the layers, and cannot be extracted in a front direction (layering direction) of the light-emitting device. As a result, such a parallel component becomes a factor that lowers light extraction efficiency.

In response, for example, PTL 1 discloses forming a reflective layer on an inclined face of the bank to cause the light (guided light component) propagating in the EL layer to exit in a direction perpendicular to the electrode face (in other words, in the front direction of the light-emitting device).

### CITATION LIST

### Patent Literature

PTL 1: JP 4534054 B

### SUMMARY OF INVENTION

### Technical Problem

According to PTL 1, a plurality of banks, each including an upper face, a bottom face, and two side surfaces that form a cross section having a tapered shape, are formed on a substrate spaced apart and extending parallel to one another. An angle (inclination angle) formed by the bottom face and the side surface of the bank is equal to or greater than 400 and equal to or less than 50°. In PTL 1, a lower electrode layer is formed covering an area between adjacent banks and, of the side surfaces of the banks adjacent to each other, the inclined faces having the angle described above and facing each other, and the lower electrode layer on the inclined faces is covered with an insulating film having light-transmitting properties, thereby forming a reflective layer on the inclined faces of the banks. As a result, the lower electrode layer on a sidewall of the bank is a reflective layer covered with the insulating film and does not function as an electrode.

Accordingly, in the light-emitting device described in PTL 1, the light extraction efficiency can hardly be called sufficient, and the concern arises that the guided light component cannot be efficiently extracted when the opening size of the bank is large, yet the drive voltage rises when the opening size of the bank is small.

The disclosure has been made in view of the problems in the prior art described above and, according to an aspect of the disclosure, provides a light-emitting device more capable of improving a light extraction efficiency and suppressing a rise in drive voltage than ever before.

### Solution to Problem

To solve the problems described above, a light-emitting device according to an aspect of the disclosure includes a bank provided with a through-hole including an opening sidewall, the opening sidewall being inclined, a lower layer electrode formed on the bank, closing the through-hole, an upper layer electrode formed above the lower layer electrode, and an EL layer formed between the lower layer electrode and the upper layer electrode, adjacently to the lower layer electrode and the upper layer electrode. The lower layer electrode is provided with an inclined face along at least a portion of the opening sidewall. The EL layer includes at least a light-emitting layer and is provided with an inclined face along at least a portion of the inclined face of the lower layer electrode. The upper layer electrode is provided with an inclined face along at least a portion of the inclined face of the EL layer.

### Advantageous Effects of Invention

According to the aspect of the disclosure, light propagating in the EL layer by total reflection can be reflected by the inclined face of the lower layer electrode and extracted to the outside, and can be emitted at least in part above the opening sidewall, thereby making it possible to increase a light-emitting area. Further, according to the aspect of the disclosure, the lower layer electrode itself formed on the opening sidewall also functions as an electrode, making it possible to increase an electrode area. As a result, a rise in a drive voltage can be suppressed.

Accordingly, according to the aspect of the disclosure, it is possible to provide a light-emitting device more capable of improving a light extraction efficiency and suppressing a rise in drive voltage than ever before.

### BRIEF DESCRIPTION OF DRAWINGS

FIG. 1 is a plan view illustrating an example of a schematic configuration of main portions of a display device according to a first embodiment.

FIG. 2 is a plan view illustrating an example of a schematic configuration of the main portions of the display device according to the first embodiment, as viewed from above a second electrode of each subpixel of the display device.

FIG. 3 is a cross-sectional view illustrating a schematic configuration of the main portions of the display device according to the first embodiment.

FIG. 4 is a view schematically illustrating an example of a layered structure of each light-emitting region of light-emitting elements of the display device according to the first embodiment.

FIG. 5 is a flowchart illustrating an example of a manufacturing process of the display device according to the first embodiment.

FIG. 6 is a flowchart illustrating an example of a formation process of a light-emitting element layer indicated in step S4 in FIG. 5.

FIG. 7 is a cross-sectional view illustrating an optical path of light in the light-emitting region of the light-emitting element layer of the display device according to the first embodiment.

FIG. 8 is a diagram illustrating an optical microscope photograph showing a light emission state of the light-emitting regions of the display device according to the first embodiment.

FIG. 9 is a cross-sectional view illustrating an optical path of light in a light-emitting region of a comparative light-emitting element in which a second electrode is not formed on an opening sidewall of a bank.

FIG. 10 is a diagram illustrating an optical microscope photograph showing a light emission state of the light-emitting regions of the comparative light-emitting element illustrated in FIG. 9.

FIG. 11 is a plan view illustrating an example of a schematic configuration of main portions of the display device according to a second embodiment, as viewed from above the second electrode of each subpixel of the display device.

FIG. 12 is a view schematically illustrating an example of a layered structure of each light-emitting region of light-emitting elements of each color of a display device according to a third embodiment.

FIG. 13 is a graph showing a relationship between a layer thickness of ITO on a reflective electrode and a light extraction efficiency in the second electrode in each light-emitting region of the light-emitting elements of each color in the display device according to the third embodiment.

FIG. 14 is a cross-sectional view illustrating a schematic configuration of main portions of the light-emitting element layer of the display device according to a fourth embodiment, together with an optical path of light in the light-emitting region in the light-emitting element layer.

FIG. 15 is a cross-sectional view illustrating a schematic configuration of main portions of the light-emitting element layer of the display device according to a fifth embodiment, together with an optical path of light in the light-emitting region in the light-emitting element layer.

### DESCRIPTION OF EMBODIMENTS

### First Embodiment

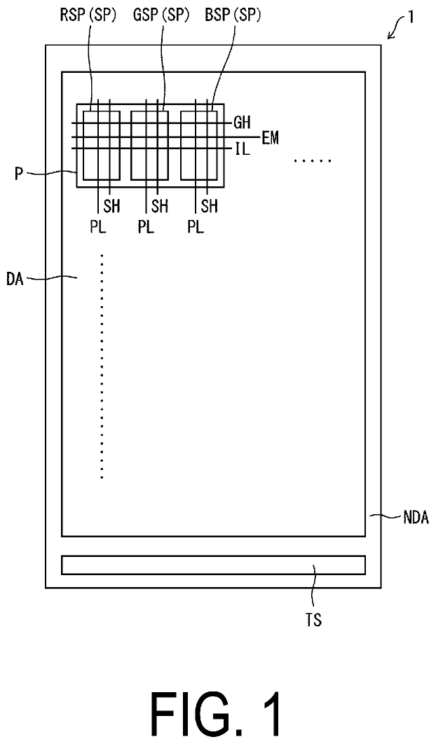

An embodiment of the disclosure will be described as follows with reference to FIG. 1 to FIG. 10. Note that, in the following, description is made using, as an example, a case in which a light-emitting device according to the present embodiment is a display device.

### Schematic Configuration of Display Device

FIG. 1 is a plan view illustrating an example of a schematic configuration of main portions of a display device 1 (light-emitting device) according to the present embodiment.

As illustrated in FIG. 1, the display device 1 includes a display region DA (pixel region) including a plurality of subpixels SP and a frame region NDA provided around the display region DA, surrounding the display region DA.

The frame region NDA is a non-display region. In the frame region NDA, a terminal portion TS into which is input a signal for driving each subpixel SP is provided. Note that the terminal portion TS may be provided with an electronic circuit board (not illustrated) such as an integrated circuit (IC) chip and a flexible printed circuit (FPC) board, for example.

In the display region DA, for example, a plurality of wiring lines including a plurality of gate wiring lines GH, a plurality of light emission control lines EM, and a plurality of initialization potential lines IL extend in a row direction. Further, in the display region DA, for example, a plurality of wiring lines including a plurality of power source lines PL and a plurality of source wiring lines SH extend in a column direction. The plurality of subpixels SP are provided in a matrix shape, for example, respectively corresponding to intersecting portions of the gate wiring lines GH and the source wiring lines SH.

The display device 1 includes, as the subpixels SP, a subpixel RSP of a red color (R) that emits red light, a subpixel GSP of a green color (G) that emits green light, and a subpixel BSP of a blue color (B) that emits blue light, for example. Note that, in the present embodiment, when there is no particular need to distinguish between the subpixel RSP, the subpixel GSP, and the subpixel BSP, these are collectively referred to simply as “subpixel SP.”

FIG. 1 illustrates an example in which the display device 1 includes a plurality of pixels P each including the subpixels SP of three colors, exhibiting the three different colors RGB, and the plurality of pixels P are provided in a matrix shape in the display region DA. Further, FIG. 1 illustrates an example in which the subpixels SP of the colors RGB are repeatedly arrayed side-by-side in this order in an extending direction of the gate wiring line GH, and a plurality of the subpixels SP are arrayed side-by-side for each color in the extending direction of the source wiring line SH. However, the above is merely an example, and the display device 1 may include subpixels SP other than the subpixels of RGB. Further, the arrays of the subpixels SP are also not limited to the above arrays.

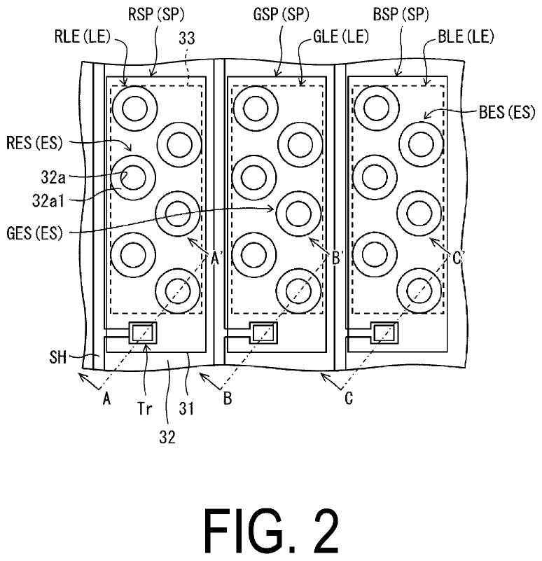

FIG. 2 is a plan view illustrating an example of a schematic configuration of the main portions of the display device 1 according to the present embodiment, as viewed from above a second electrode 33 of each subpixel SP of the display device 1.

The display device 1 is a self-luminous display device. As illustrated in FIG. 2, in each subpixel SP, a self-luminous light-emitting element LE is formed. In each light-emitting element LE, a plurality of light-emitting regions (small hole light-emitting regions) ES partitioned into small hole shapes by a bank 32 are formed. The light-emitting regions ES are separated from one another by the bank 32 that is a non-light-emitting region. Therefore, the display device 1 has a configuration in which the light-emitting element LE including the plurality of light-emitting regions ES surrounded by the bank 32 is provided in each subpixel SP.

In the subpixel RSP, a light-emitting element RLE of a red color that emits red light (red light-emitting element) is provided. In the subpixel GSP, a light-emitting element GLE of a green color that emits green light (green light-emitting element) is provided. In the subpixel BSP, a light-emitting element BLE of a blue color that emits blue light (blue light-emitting element) is provided. Note that the luminescent colors of the light-emitting regions ES of the light-emitting elements LE provided in the same subpixel SP are all the same. Accordingly, in the subpixel RSP of a red color, a plurality of light-emitting regions RES of a red luminescent color (red light-emitting regions) are provided as the light-emitting regions ES. In the subpixel GSP of a green color, a plurality of light-emitting regions GES of a green luminescent color (green light-emitting regions) are provided as the light-emitting regions ES. In the subpixel BSP of a blue color, a plurality of light-emitting regions BES of a blue luminescent color (blue light-emitting regions) are provided as the light-emitting regions ES. Thus, the display region DA is provided with a plurality of the light-emitting regions ES in the plurality of light-emitting elements LE having luminescent colors different from one another.

Note that, in the present embodiment, when there is no particular need to distinguish between the light-emitting element RLE, the light-emitting element GLE, and the light-emitting element BLE, the light-emitting element RLE, the light-emitting element GLE, and the light-emitting element BLE are collectively simply referred to as “light-emitting element LE.” Further, note that, in the present embodiment, when there is no particular need to distinguish between the light-emitting element RLE, the light-emitting element GLE, and the light-emitting element BLE, the light-emitting region RES, the light-emitting region GES, and the light-emitting region BES are collectively simply referred to as “light-emitting region ES.” Further, the individual layers in the light-emitting regions ES of the light-emitting elements LE are also similarly collectively named when there is no particular need to distinguish between the light-emitting region RES, the light-emitting region GES, and the light-emitting region BES.

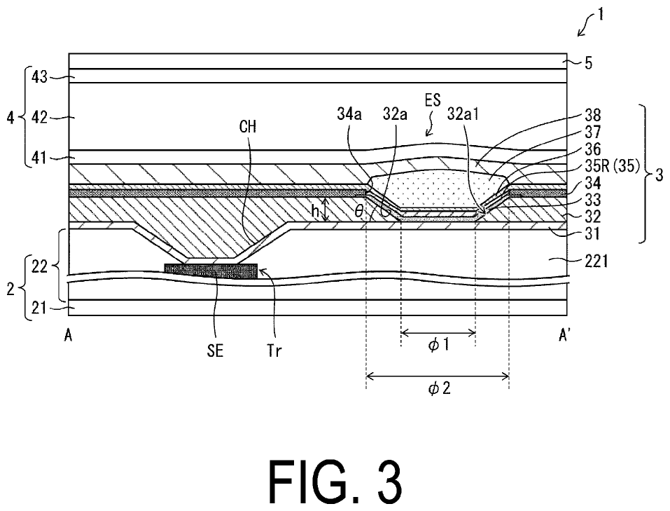

FIG. 3 is a cross-sectional view illustrating a schematic configuration of main portions of the display device 1 according to the present embodiment. Note that FIG. 3 illustrates, as an example, a cross section corresponding to the cross section taken along line A-A′ illustrated in FIG. 2 in the display device 1 provided with an EL layer 35R including the light-emitting layer that emits red light. However, the cross section taken along the line A-A′, the cross section taken along line B-B′, and the cross section taken along line C-C′ illustrated in FIG. 2 have the same cross-sectional configuration except that the light-emitting elements LE in each cross section include light-emitting layers that emit light of colors different from one another. Therefore, in the following description, the schematic configuration of the cross section taken along the line A-A′ will be described as a configuration common to the cross section taken along the line A-A′, the cross section taken along the line B-B′, and the cross section taken along the line C-C′ without distinguishing the configuration for each subpixel SP (light-emitting element LE).

As illustrated in FIG. 3, the display device 1 includes an array substrate 2, a light-emitting element layer 3, and a sealing layer 4 in this order. In the following, a direction from the array substrate 2 toward the sealing layer 4 is referred to as an upward direction, and a direction opposite thereof is referred to as a downward direction. Further, in the following, a layer formed in a process prior to that of a layer being compared is referred to as a “lower layer,” and a layer formed in a process after that of a layer being compared is referred to as an “upper layer.” Note that, as illustrated in FIG. 3, a function layer 5 selected as appropriate according to application may be provided on the sealing layer 4 in the display device 1.

The array substrate 2 has a configuration in which a thin film transistor layer 22 is provided on an insulating substrate 21.

The insulating substrate 21 is a support body that supports the individual layers from the thin film transistor layer 22 to the function layer 5. The insulating substrate 21 may be, for example, an inorganic substrate made of an inorganic material such as glass, quartz, or ceramics, or a flexible substrate made primarily of a resin such as polyethylene terephthalate or polyimide. When the insulating substrate 21 is a flexible substrate, the insulating substrate 21 may be formed of a resin film (resin layer) such as a polyimide film, or may be formed of two resin films and an inorganic insulating film interposed between these resin films.

Further, on a surface of the insulating substrate 21, a barrier layer may be provided to prevent foreign matter such as water and oxygen from entering the thin film transistor layer 22 and the light-emitting element layer 3. Such a barrier layer can be constituted by a silicon oxide film, a silicon nitride film, a silicon oxynitride film, or a layered film of these, formed by chemical vapor deposition (CVD), for example.

Note that, when the display device 1 is a top-emission display device that emits light from a side opposite to the insulating substrate 21, the insulating substrate 21 used is not particularly limited. However, when the display device 1 is a bottom-emission display device that emits light from a back face side of the insulating substrate 21, the insulating substrate 21 used is a light-transmissive substrate that is transparent or semi-transparent.

A subpixel circuit that controls the light-emitting element layer 3 and a plurality of wiring lines including the gate wiring line GH and the source wiring line SH that are connected to the subpixel circuit are formed in the thin film transistor layer 22. The subpixel circuit is provided for each subpixel SP in correspondence with each subpixel SP in the display region DA. The subpixel circuit includes a plurality of thin film transistors including a thin film transistor Tr illustrated in FIG. 2 and FIG. 3. The plurality of thin film transistors are electrically connected to a plurality of wiring lines including wiring lines such as the gate wiring line GH and the source wiring line SH described above. Note that, as these thin film transistors, a conventionally known structure can be employed, and the structure is not particularly limited.

On a surface of the thin film transistor layer 22, provided is a flattening film 221 covering the plurality of thin film transistors, flattening surfaces of the plurality of thin film transistors provided in the thin film transistor layer 22 and including the thin film transistor Tr. The flattening film 221 can be formed of, for example, a coatable organic insulating material such as polyimide or acrylic resin.

The light-emitting element layer 3 includes the plurality of light-emitting elements LE described above. Further, the light-emitting element layer 3 is provided with the plurality of light-emitting regions ES described above in each light-emitting element LE. As described above, these light-emitting regions ES include the light-emitting region RES, the light-emitting region GES, and the light-emitting region BES in terms of pixel units. Note that, in the present embodiment, as described above, a plurality of light-emitting regions ES having the same luminescent color are provided in the same subpixel SP.

The light-emitting element layer 3 includes a first electrode 31, the bank 32 (wall body), the second electrode 33, an edge cover 34, an electroluminescent (EL) layer 35, a third electrode 36, a high-refractive-index material layer 37, and a low-refractive-index material layer 38 in this order from the thin film transistor layer 22 side.

The light-emitting element LE includes, in each light-emitting region ES, the second electrode 33, the EL layer 35 including at least a light-emitting layer, the third electrode 36, the high-refractive-index material layer 37 (first refractive index layer), and the low-refractive-index material layer 38 (second refractive index layer). Note that layers between the second electrode 33 and the third electrode 36 are collectively referred to as the EL layer 35 in the present embodiment.

The first electrode 31 is a connection electrode of the thin film transistor Tr in each subpixel circuit. As illustrated in FIG. 2 and FIG. 3, the first electrode 31 is formed on the flattening film 221 in an island shape for each subpixel SP, covering the entire corresponding subpixel SP (in other words, the entire subpixel region) in plan view, for example. The first electrode 31 in each subpixel SP is connected (electrically connected), via a contact hole CH provided in the flattening film 221 for each subpixel SP, to a source electrode SE of the thin film transistor Tr of the subpixel SP connected to the source wiring line SH.

Further, on the flattening film 221, the bank 32 including an opening 32a (through-hole) for exposing a portion of the first electrode 31 is formed covering the first electrode 31 as a film for forming the light-emitting region ES having a small hole shape.

The bank 32 is an organic insulating film formed of a photosensitive resin such as a polyimide or acrylic resin, for example.

As illustrated in FIG. 2 and FIG. 3, the bank 32 according to the present embodiment is provided with a plurality of the openings 32a (through-holes) as the through-hole described above, each having a small hole shape and including an opening sidewall 32al that is inclined. In the present embodiment, as illustrated in FIG. 2, a plurality of the openings 32a having a small hole shape described above are provided in one subpixel SP.

Desirably, the openings 32a are formed with opening sizes (diameters) thereof decreasing toward a lower side. Accordingly, desirably, the opening sidewall 32a1, which is an internal wall of the opening 32a and surrounds the opening 32a, is inclined with the opening size of the opening 32a decreasing toward the lower side, forming the opening 32a having a reverse tapered shape in a cross-sectional view. In other words, preferably, the opening sidewall 32al of the opening 32a is provided with an inclined face having a tapered shape in which the opening size of the opening 32a decreases toward the lower side (that is, an inclined face having a reverse tapered shape).

As illustrated in FIG. 3, in the bank 32, given θ(°) as an angle (inclination angle) formed by the inclined face (in other words, the inclined opening sidewall 32al) and the lower face (bottom face) of the bank 32, θ is preferably 15°<0<40°, and more preferably 20°<0 30°.

Further, as illustrated in FIG. 3, given φ1 (μm) as the opening size (diameter) on a lower side of the bank 32, φ1 is preferably 10 μm≤φ1≤20 μm, and more preferably 12 μm≤φ1≤15 μm.

Note that, in the present embodiment, an upper side of the bank 32 refers to the second electrode 33 side of the bank 32, and the lower side of the bank 32 refers to the opposite side (side opposite to the second electrode 33 side), that is, the insulating substrate 21 side of the bank 32. Further, the opening size on the lower side of the bank 32 refers to an aperture diameter on a lower end side of the opening 32a of the bank 32.

Further, as illustrated in FIG. 3, given h (μm) as a height of the bank 32 at a portion other than the contact hole CH, h is preferably 1 μm≤h≤4 μm, and more preferably 2 μm≤h≤3 μm. Note that the height of the bank 32 at a portion other than the contact hole CH is equal to the height between an upper end and a lower end of the opening 32a of the bank 32.

The second electrode 33 is a lower layer electrode of the light-emitting element LE. The second electrode 33 is formed on the bank 32 along a surface of the bank 32, covering the openings 32a, including the inclined faces of the opening sidewalls 32al, of the bank 32 positioned in each subpixel SP.

Thus, the second electrode 33 is provided with an inclined face having a tapered shape and formed on the opening sidewall 32al along the opening sidewall 32al.

Further, at each opening 32a of the bank 32, the second electrode 33 is connected (electrically connected) to the first electrode 31 by being in contact with portions of the first electrode 31 exposed from these openings 32a. Therefore, the second electrode 33 is electrically connected, via the first electrode 31, to the source electrode SE of the thin film transistor Tr connected to the source wiring line SH.

As illustrated in FIG. 2, the second electrode 33 is formed as an island electrode (subpixel electrode) in an island shape for each subpixel SP, for example, overlapping a portion of the first electrode 31 in each subpixel SP. Therefore, the first electrode 31 and the second electrode 33 are provided in common to each light-emitting region ES in each subpixel SP, and one first electrode 31 and one second electrode 33 are provided in each subpixel SP (in other words, each light-emitting element LE).

The second electrode 33 is covered with the edge cover 34 including a plurality of openings 34a (through-holes) corresponding to the openings 32a, opening the openings 32a of the bank 32. The edge cover 34 is formed on the bank 32, covering an upper face of the bank 32 and a portion of the second electrode 33 positioned on the upper face of the bank 32. A portion of the second electrode that covers the openings 32a of the bank 32 is not covered with the edge cover 34 and is exposed from the openings 34a of the edge cover 34. According to the present embodiment, a region inside the opening 34a of this edge cover 34 (that is, the region inside the opening 32a of the bank 32 exposed by the opening 34a of the edge cover 34) is the light-emitting region ES of each subpixel SP. Accordingly, the light-emitting regions ES are formed in correspondence with the openings 32a of the bank 32, respectively.

The edge cover 34 is an insulating layer for preventing a short circuit between the second electrode 33 and the third electrode 36 in each light-emitting region ES resulting from thinning of the EL layer 35 and an electric field concentration at an end portion of the light-emitting region of each subpixel SP, in other words, at the upper end of the opening 32a of the bank 32.

As a material of the edge cover 34, an inorganic insulating film such as a silicon nitride film or a silicon oxide film, or an organic insulating film made of a photosensitive resin such as a polyimide or acrylic resin is used, for example.

An opening size (diameter) of the edge cover 34 is approximately equal to an opening size (diameter) of the upper side of the bank 32. Here, the opening size on the upper side of the bank 32 refers to an aperture diameter on the upper end side of the opening 32a of the bank 32.

Given φ2 (μm) as the opening size (diameter) of the edge cover 34, φ2 is preferably 12 μm≤φ2≤65 μm (where φ2>φ1), and more preferably 18 μm≤φ2<32 μm (where φ2>φ1).

In the present embodiment, as described above, the openings 34a corresponding to each opening 32a of the bank 32 are formed in the edge cover 34, and thus the opening size of the edge cover 34 and the opening size of the upper side of the bank are the same size. Therefore, in the present embodiment, the opening size of the upper side of the bank is preferably within a range from 12 μm to 65 μm and larger than the opening size (φ1) of the lower side of the bank, and preferably within a range from 18 μm to 32 μm and larger than the opening size (φ1) of the lower side of the bank.

Note that a thickness of the edge cover 34 is not particularly limited as long as the edge cover 34 is formed to a thickness capable of insulating the second electrode 33 from the third electrode 36. The edge cover 34 can be set to a thickness similar to that of a conventionally known insulating layer or edge cover, for example. However, to suppress step disconnection of the third electrode 36, the edge cover 34 is preferably thinly formed within a range in which insulation is possible.

The third electrode 36 is an upper layer electrode of the light-emitting element LE. The third electrode 36 is formed in a solid shape in the pixel region as a common electrode common to all subpixels SP.

One of the second electrode 33 and the third electrode 36 is an anode (anode electrode) and the other is a cathode (cathode electrode). The anode is an electrode that supplies positive holes (holes) to the EL layer 35 when a voltage is applied. The cathode is an electrode that supplies electrons to the EL layer 35 when a voltage is applied.

The first electrode 31, the second electrode 33, and the third electrode 36 may each be a single layer or may each have a layered structure.

Of the first electrode 31, the second electrode 33, and the third electrode 36, the electrode on the light extraction surface side must have light-transmitting properties.

Therefore, when the display device 1 is a top-emission display device, a light-transmissive electrode having light-transmitting properties is used for the third electrode 36, and a so-called reflective electrode having light reflectivity, for example, is used for the second electrode 33.

Note that, when the second electrode 33 is a reflective electrode, the first electrode 31 may be a light-transmissive electrode or may be a reflective electrode.

The light-transmissive electrode is formed of a light-transmissive material such as indium tin oxide (ITO), indium zinc oxide (IZO), silver nanowire (AgNW), a thin film of magnesium-silver (MgAg) alloy, or a thin film of silver (Ag), for example.

The reflective electrode is formed of a light-reflective material, for example, a metal such as Ag or aluminum (Al), or an alloy including these metals. Note that the reflective electrode may be obtained by layering a light-transmissive material and a light-reflective material.

The EL layer 35 is formed on the second electrode 33 along a surface of the second electrode 33, covering the surface of the second electrode 33 exposed from the openings 34a of the edge cover 34, including the surface of the second electrode 33 formed on the inclined face of the opening sidewall 32al of the bank 32 (that is, the inclined face of the second electrode 33).

Thus, the EL layer 35 is provided with an inclined face having a tapered shape and formed on the inclined face of the second electrode 33 along that inclined face.

The third electrode 36 is formed on the EL layer 35 and the edge cover 34, along surfaces of the EL layer 35 and the edge cover 34, covering the EL layer 35, including the surface of the EL layer 35 formed on the inclined face of the second electrode 33. In other words, the third electrode 36 is formed on the EL layer 35 and the edge cover 34 along the surfaces of the EL layer 35 and the edge cover 34, covering the EL layer 35, including the inclined face of the EL layer 35 formed above the inclined face of the opening sidewall 32al of the bank 32.

Thus, the third electrode 36 is provided with an inclined face having a tapered shape and formed on the inclined face of the EL layer 35, along that inclined face.

For this reason, each of the second electrode 33, the EL layer 35, and the third electrode 36 includes, in the opening 32a of the bank 32, a trench portion including a sidewall having a tapered shape (inner wall, inclined face) following the shape of the opening sidewall 32a1 of the opening 32a.

Thus, the EL layer 35 is a layer between the second electrode 33 and the third electrode 36 in the light-emitting element LE, and includes at least a light-emitting layer.

The light-emitting element LE may be, for example, a quantum dot light-emitting diode (QLED) or may be an organic light-emitting diode (OLED). When the light-emitting element LE is a QLED, a quantum dot (QD) light-emitting layer including quantum dots (QDs) as a light-emitting material is used as the light-emitting layer. When the light-emitting element LE is an OLED, an organic light-emitting layer that uses an organic light-emitting material as the light-emitting material is used for the light-emitting layer.

When the light-emitting element LE is a QLED, positive holes and electrons recombine inside the light-emitting layer in response to a drive current between the anode and the cathode, and light is emitted when excitons generated in this manner transition from a conduction band level to a valence band level of the QDs. When the light-emitting element LE is an OLED, positive holes and electrons recombine inside the light-emitting layer in response to a drive current between the anode and the cathode, and light is emitted as a result of excitons, which are generated by the recombination, falling into a ground state. However, the light-emitting element LE may be a light-emitting element other than the OLED or the QLED (for example, an inorganic light-emitting diode).

Note that the EL layer 35 may be a single layer type formed only of a light-emitting layer, or may be a multi-layer type including a function layer other than the light-emitting layer. The EL layer 35 may include, for example, at least one layer of a hole injection layer (HIL), a hole transport layer (HTL), an electron transport layer (ETL), and an electron injection layer (EIL) in addition to the light-emitting layer.

When the light-emitting element LE is a QLED, each of the HIL, the HTL, the ETL, and the EIL may be formed of an organic material or may be formed of an inorganic material. When the light-emitting element LE is an OLED, an organic material is used for each of the HIL, the HTL, the ETL, and the EIL.

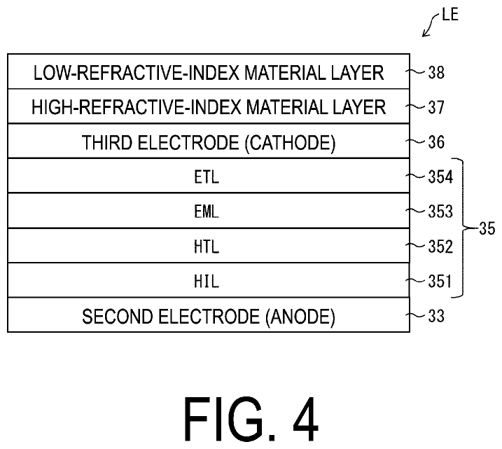

FIG. 4 is a view schematically illustrating an example of a layered structure of each light-emitting region ES of light-emitting elements LE of the display device 1 according to the present embodiment. Note that FIG. 4 illustrates, as an example, a case in which the display device 1 is a top-emission display device having a conventional structure. In this case, the second electrode 33 is an anode (pattern anode) patterned in an island shape, and the third electrode 36 is a cathode (common cathode) provided in common to all the subpixels SP. Further, the second electrode 33 is formed of a reflective electrode, and the third electrode 36 is formed of a material having optical transparency.

In the present embodiment, for the third electrode 36, a light-transmissive electrode made of a light-transmissive material such as ITO, IZO, AgNW, a thin film of an MgAg alloy, or a thin film of Ag is used. Further, for the second electrode 33, a reflective electrode formed of a layered body obtained by layering an Ag alloy, including Ag, and ITO in the order of ITO/Ag alloy/ITO from the lower layer side, a layered body obtained by layering Ag and ITO in the order of ITO/Ag/ITO from the lower layer side, a layered body obtained by layering Al and IZO in the order of A/IZO from the lower layer side, or the like is used.

Further, in the example illustrated in FIG. 4, an HIL 351, an HTL 352, an EML 353, and an ETL 354 are formed as the EL layer 35 in this order from the second electrode 33 side, between the second electrode 33 and the third electrode 36. Note that, in the layering order described above, the second electrode 33 serves as an anode and the third electrode 36 serves as a cathode as described above. The display device 1 may have an inverted structure, and thus the second electrode 33 may be a cathode and the third electrode 36 may be an anode. In this case, the layering order of the EL layer 35 is reversed from that in FIG. 4.

Note that, although the following description will be made with reference to an example in which the light-emitting element LE is a QLED, the present embodiment is not limited thereto, and the light-emitting element LE may be an OLED or may be an inorganic light-emitting diode as described above.

The HIL 351 has hole transport properties and promotes the injection of positive holes from the second electrodes 33 into the EML 353. A known hole transport material can be used for the HIL 351. Examples of the hole transport material used for the HIL 351 include a composite (abbreviated PEDOT:PSS) of poly(3,4-ethylenedioxythiophene) (PEDOT) and polystyrene sulfonic acid (PSS), nickel oxide, (NiO) and copper thiocyanate (CuSCN). Only one type of these hole transport materials may be used, or two or more types thereof may be mixed and used as appropriate.

The HTL 352 has hole transport properties and transports the positive holes injected from the HIL 351 to the EML 353. A known hole transport material can be used for the HTL 352. Examples of the hole transport material used for the HIL 351 include poly[(9,9-dioctylfluorenyl-2,7-diyl)-co-(4,4′-(N-4-sec-butylphenyl)) diphenylamine)](abbreviated “TFB”), poly[N,N′-bis(4-butylphenyl)-N,N′-bis(phenyl)-benzidine](abbreviated “p-TPD”), and polyvinyl carbazole (abbreviated “PVK”). Only one type of these hole transport materials may be used, or two or more types thereof may be mixed and used as appropriate.

The ETL 354 has electron transport properties and transports electrons from the third electrode 36 to the EML 353. A known electron transport material can be used for the ETL 354. Examples of the electron transport material used for the ETL 354 include zinc oxide (ZnO) and magnesium zinc oxide (MgZnO). Only one type of these electron transport materials may be used, or two or more types thereof may be mixed and used as appropriate.

The EML 353 emits light due to the occurrence of recombination of positive holes transported from the second electrode 33 (anode) and electrons transported from the third electrode 36 (cathode).

As described above, when the light-emitting element LE is a QLED, a QD light-emitting layer including a QD as a light-emitting material is used for the EML 353.

The QD is not particularly limited, and various known QDs can be employed. The QD may include, for example, a semiconductor material formed of an element of at least one type selected from the group consisting of cadmium (Cd), sulfur (S), tellurium (Te), selenium (Se), zinc (Zn), indium (In), nitrogen (N), phosphorus (P), arsenic (As), antimony (Sb), aluminum (Al), gallium (Ga), lead (Pb), silicon (Si), germanium (Ge), and magnesium (Mg). Further, the QD may be a two-component core type, a three-component core type, a four-component core type, a core-shell type, or a core multi-shell type.

Note that, as described above, in the subpixel RSP, the light-emitting region RES is provided as the light-emitting region ES. In the light-emitting region RES, the EL layer 35 including the EML 353 that uses a red QD as a light-emitting material is formed as the EL layer 35 (in this case, the EL layer 35R). Further, the subpixel GSP is provided with the light-emitting region GES as the light-emitting region ES. In the light-emitting region GES, the EL layer 35 including the EML 353 that uses a green QD as a light-emitting material is formed as the EL layer 35. The subpixel BSP is provided with the light-emitting region BES as the light-emitting region ES. In the light-emitting region BES, the EL layer 35 including the EML 353 that uses a blue QD as a light-emitting material is formed as the EL layer 35.

The luminescent colors of the light-emitting regions ES provided in the same subpixel SP (in other words, the same light-emitting element LE) are all the same. Accordingly, the same subpixel SP includes the same kind of QD.

Therefore, the EML 353 may be formed into an island shape for each light-emitting region ES, or may be formed into an island shape for each subpixel SP.

In either case, as described above, the light-emitting regions ES are formed in correspondence with each opening 32a of the bank 32 and, in the present embodiment, the bank 32 includes a plurality of the openings 32a in each subpixel SP. Therefore, the EMLs 353 having the same luminescent color are formed in the openings 32a in each subpixel SP.

Note that the layers other than the EML 353 included in the EL layer 35 may be formed into island shapes for each light-emitting region ES, may be formed into island shapes for each subpixel SP, or may be formed into solid shapes common to all subpixels SP. FIG. 3 illustrates an example in which each layer in the EL layer 35 is formed into an island shape for each subpixel SP.

The high-refractive-index material layer 37 and the low-refractive-index material layer 38 function as optical layers that refract light emitted from the EML 353, and also function as protection layers that protect the third electrode 36.

The high-refractive-index material layer 37 is formed at a position corresponding to the openings 32a of the bank 32 on the third electrode 36, filling recesses (trench portions) of the third electrode 36 in the openings 32a of the bank 32. In other words, the high-refractive-index material layer 37 is formed in the openings 32a of the bank 32 in which the second electrode 33, the EL layer 35, and the third electrode 36 are formed, filling the openings 32a (strictly, the trench portions of the third electrode 36).

The low-refractive-index material layer 38 is formed over the third electrode 36 and adjacent to the high-refractive-index material layer 37, covering the high-refractive-index material layer 37.

The high-refractive-index material layer 37 is formed of a material having a refractive index higher than that of the low-refractive-index material layer 38. As a result, a portion of light incident on the high-refractive-index material layer 37 can be reflected at an interface with the low-refractive-index material layer 38 and guided to the reflective surface formed on the bank 32, thereby contributing to an improvement in the brightness in the front direction. That is, according to the present embodiment, by providing the high-refractive-index material layer 37 as described above, it is possible to efficiently utilize the second electrode 33 as the reflective layer on the opening sidewall 32al.

On the other hand, the low-refractive-index material layer 38 is formed of a material having a refractive index lower than the refractive index of the high-refractive-index material layer 37. With the high-refractive-index material layer 37 formed in the openings 32a and the low-refractive-index material layer 38 formed on the high-refractive-index material layer 37 and adjacent to the high-refractive-index material layer 37, light from the EML 353 is totally reflected at the interface between the high-refractive-index material layer 37 and the low-refractive-index material layer 38 and directed toward the inclined faces of the opening sidewalls 32a1 of the openings 32a, making it possible to extract the guided light component from the light extraction direction (front direction).

The refractive index of the high-refractive-index material layer 37 is not particularly limited as long as the index is higher than the refractive index of the low-refractive-index material layer 38, but is desirably 1.7 or greater, and more desirably 1.8 or greater. Note that the refractive index of the high-refractive-index material layer 37 may be as high as possible as long as the refractive index difference from the refractive index of the low-refractive-index material layer 38 can be increased, and the lower limit is not particularly limited. However, when a large amount of an additive for improving the refractive index is included, there is a concern that a patterning performance may deteriorate. Therefore, the refractive index of the high-refractive-index material layer 37 is desirably 2.0 or less.

Examples of the high-refractive-index material used for forming the high-refractive-index material layer 37 include at least one organic insulating material selected from the group consisting of an acrylic resin, a siloxane-based resin, and materials obtained by adding an oxide to these resins.

The refractive index of the low-refractive-index material layer 38 is not particularly limited as long as the index is lower than the refractive index of the high-refractive-index material layer 37, but is desirably 1.4 or less, and more desirably 1.3 or less. Note that the refractive index of the low-refractive-index material layer 38 may be as high as possible as long as the refractive index difference from the refractive index of the high-refractive-index material layer 37 can be increased, and the upper limit thereof is not particularly limited. However, increasing a void space to reduce the refractive index raises reliability concerns. For this reason, the refractive index of the low-refractive-index material layer 38 is desirably 1.2 or greater.

Examples of the low-refractive-index material used for forming the low-refractive-index material layer 38 include a siloxane-based resin. Note that, as in the case of the high-refractive-index material layer 37, the low-refractive-index material layer 38 used may be one type or a combination of two or more types as appropriate. Note that, in the disclosure, the refractive index indicates an absolute refractive index in a visible light region.

Further, each of the high-refractive-index material layer 37 and the low-refractive-index material layer 38 may be a single layer or may have a layered structure.

Note that the high-refractive-index material layer 37 is desirably formed filling the openings 32a of the bank 32 (more strictly, the trench portions of the third electrode 36) as described above in order to efficiently extract the light reflected by the second electrode 33 covering the inclined faces of the opening sidewalls 32a1 of the bank 32.

Further, to prevent color mixing, the high-refractive-index material layer 37 is desirably formed into an island shape for each opening 32a of the bank 32 (in other words, for each light-emitting region ES).

Therefore, the high-refractive-index material layer 37 on the lower ends of the openings 32a of the bank 32 is preferably thicker than a height h of the bank 32 (more strictly, a depth of the trench portion of the third electrode 36). Therefore, the high-refractive-index material layer 37 on the lower ends of the bank openings 32a is desirably 1.0 μm or greater, and more desirably 2 μm or greater. On the other hand, when the high-refractive-index material layer 37 is too thick, it is difficult to achieve high resolution.

Therefore, the high-refractive-index material layer 37 on the lower ends of the openings 32a of the bank is preferably 4 μm or less, and more preferably 3 μm or less.

The low-refractive-index material layer 38 is a common layer provided in common to all the subpixels SP, covering the entire third electrode 36 to protect the third electrode 36. Note that a thickness of the low-refractive-index material layer 38 is not particularly limited.

The sealing layer 4 is a layer that prevents penetration of foreign matter such as water or oxygen into the light-emitting element layer 3. As illustrated in FIG. 3, the sealing layer 4 includes, for example, an inorganic sealing film 41 that covers the low-refractive-index material layer 38, an organic buffer film 42 that is an upper layer overlying the inorganic sealing film 41, and an inorganic sealing film 43 that is an upper layer overlying the organic buffer film 42.

The inorganic sealing film 41 and the inorganic sealing film 43 are light-transmissive inorganic insulating films and can be formed of inorganic insulating films such as silicon oxide films or silicon nitride films formed by CVD, for example. The organic buffer film 42 is a light-transmissive organic insulating film having a flattening effect and can be made of a coatable organic material such as acrylic. The organic buffer film 42 can be formed by, for example, ink-jet application, and a bank (not illustrated) for stopping droplets may be provided in the frame region NDA.

Note that materials and thicknesses of the thin film transistor layer 22, the second electrode 33, the EL layer 35, the third electrode 36, and the sealing layer 4 are not particularly limited, and may be similar to those in the prior art.

The function layer 5, selected as appropriate depending on the application, is formed on the sealing layer 4. The function layer 5 may be a function film having at least one of an optical compensation function, a touch sensor function, and a protection function, or may be a glass substrate such as a touch panel, a polarizer, or a cover glass, for example.

### Method for Manufacturing Display Device 1

Next, a method for manufacturing the display device 1 described above will be described.

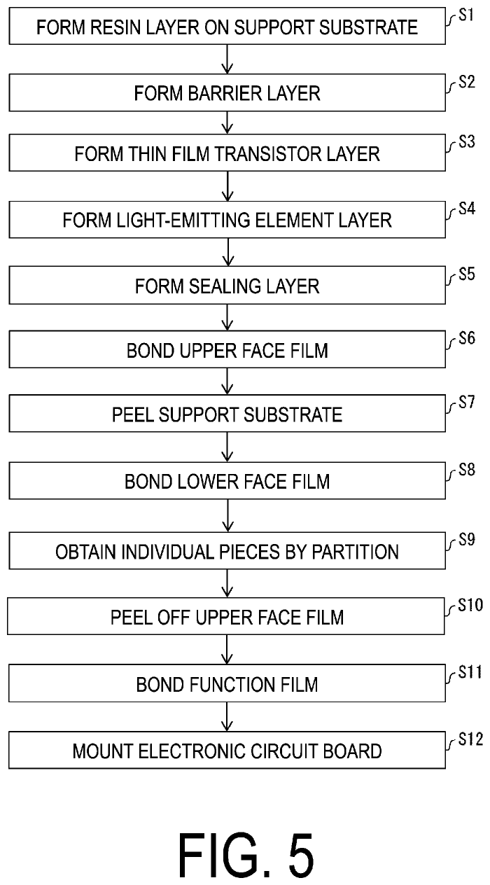

FIG. 5 is a flowchart illustrating an example of a manufacturing process for the display device 1 according to the present embodiment.

When a flexible display device is manufactured as the display device 1, first, a resin layer that is the insulating substrate 21 is formed on a light-transmissive support substrate (mother glass, for example; not illustrated), as illustrated in FIG. 5 (step S1). Next, a barrier layer is formed (step S2). Next, the thin film transistor layer 22 is formed (step S3). Next, the light-emitting element layer 3 is formed (step S4). Next, the sealing layer 4 is formed (step S5). Next, an upper face film for protection (not illustrated) is temporarily bonded onto the sealing layer 4 (step S6). Next, the support substrate is peeled from the resin layer through irradiation with laser light or the like (step S7). Next, a lower face film (not illustrated) is bonded to a lower face of the resin layer (step S8). Next, a layered body including the lower face film, the resin layer, the barrier layer, the thin film transistor layer 22, the light-emitting element layer 3, the sealing layer 4, and the upper face film is divided to obtain a plurality of individual pieces (step S9). Next, the upper face film is peeled from the obtained individual pieces (step S10), and a function film is bonded as the function layer 5 on the obtained individual pieces (step S11). Subsequently, an electronic circuit board (IC chip and FPC, for example; not illustrated) is mounted on a portion (of the frame region NDA; terminal portion TS) outward of the display region DA in which the plurality of pixels P (the plurality of subpixels SP) are formed (step S12). Note that steps S1 to S12 are performed by a display device manufacturing apparatus (including a film formation apparatus configured to perform each process of steps S1 to S5).

Note that the upper face film is bonded onto the sealing layer 4 as described above and functions as a support material when the support substrate is peeled off. Examples of the material of the upper face film include polyethylene terephthalate (PET). The lower face film is, for example, a PET film for realizing the display device 1 having excellent flexibility by being bonded to the lower face of the resin layer after the support substrate is peeled off. Note that the resin layer and the barrier layer are as described above.

Note that, although the above description describes the manufacturing method of the display device 1 having flexibility, ordinarily, processes such as formation of the resin layer and replacement of a base material are not required when the display device 1 not having flexibility is manufactured. Therefore, for example, when the display device 1 not having flexibility is to be manufactured, a process of layering including steps S2 to S5 is performed on a glass substrate, after which the process proceeds to step S9.

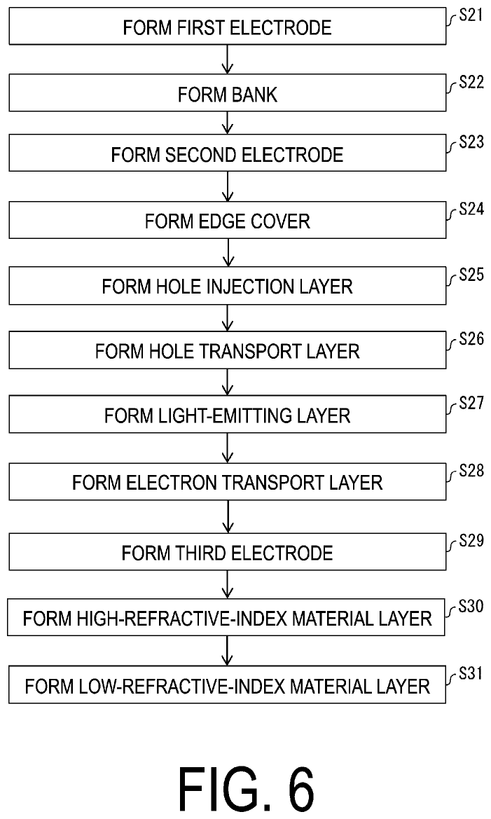

FIG. 6 is a flowchart illustrating an example of a formation process of the light-emitting element layer 3 indicated in step S4 in FIG. 5.

In the process of forming the light-emitting element layer 3, first, as illustrated in FIG. 6, the first electrode 31 is formed on the thin film transistor layer 22 (step S21). Next, the bank 32 is formed (step S22). Next, the second electrode 33 is formed (step S23). Next, the edge cover 34 is formed (step S24). Next, the HIL 351 (hole injection layer) is formed (step S25). Next, the HTL 352 (hole transport layer) is formed (step S26). Next, the EML 353 (light-emitting layer) is formed (step S27). Next, the ETL 354 (electron transport layer) is formed (step S28). Next, the third electrode 36 is formed (step S29). Next, the high-refractive-index material layer 37 is formed (step S30). Next, the low-refractive-index material layer 38 is formed (step S31).

Note that the first electrode 31, the second electrode 33, and the third electrode 36 can be formed by, for example, physical vapor deposition (PVD) such as a sputtering method or a vacuum vapor deposition technique, a spin coating method, or an ink-jet method.

Further, the bank 32 and the edge cover 34 can be formed into a desired shape by, for example, using a photolithography method to pattern a layer formed of an insulating material deposited by PVD such as a sputtering method or a vacuum vapor deposition technique, a spin-coating method, or an ink-jet method.

Further, for example, PVD such as a sputtering method or a vacuum vapor deposition technique, a spin coating method, or an ink-jet method is used for film formation of the HIL 351, the HTL 352, and the ETL 354.

When the EML 353 is the QD light-emitting layer as described above, first, for example, a lift-off template is formed in a region other than the formation region of the QD light-emitting layer (non-formation region of the QD light-emitting layer to be formed) on the underlayer (HIL 351 in the example illustrated in FIG. 4). Next, a QD dispersion including QDs and a solvent is applied onto the underlayer, and the template is peeled off. As a result, a desired QD light-emitting layer can be patterned in the region where the QD light-emitting layer is to be formed.

Note that the template can be formed by, for example, applying a resist for the template, pre-baking the resist, performing ultraviolet (UV) mask exposure, and developing the resist.

As described above, in a case in which the display device 1 includes, for example, the subpixel RSP, the subpixel GSP, and the subpixel BSP as the subpixels SP, QD light-emitting layers of three colors can be formed by repeating the processes from the formation of the template to the peeling of the template three times.

Note that, when the EML 353 is, for example, a light-emitting layer made of an organic light-emitting material, the EML 353 can be formed by, for example, a vacuum vapor deposition technique, a sputtering method, or an ink-jet method.

The high-refractive-index material layer 37 can be formed by applying a high-refractive-index material onto the third electrode 36 serving as an underlayer, pre-baking the material, performing UV mask exposure, developing the material, and then actually baking the material.

For the application of the high-refractive-index material layer 37 and the formation of the low-refractive-index material layer 38, for example, a vacuum vapor deposition technique, a spin coating method, or an ink-jet method can be used.

Note that, in the above description, a case in which the lift-off template is used only for forming the EML 353 is described as an example. However, the present embodiment is not limited thereto, and the lift-off template may also be used to form layers other than the EML 353 of the EL layer 35.

### Advantageous Effects

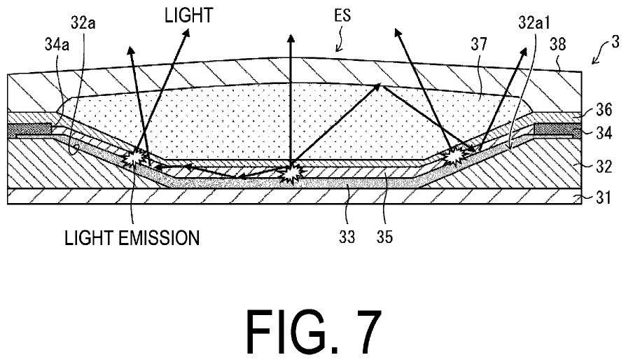

Next, advantageous effects of the display device 1 according to the present embodiment will be described below with reference to FIG. 7 to FIG. 10.

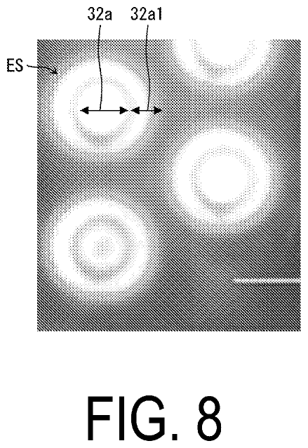

FIG. 7 is a cross-sectional view illustrating an optical path of light in the light-emitting region ES of the light-emitting element layer 3 of the display device 1 according to the present embodiment. Further, FIG. 8 is a diagram illustrating an optical microscope photograph showing a light emission state of the light-emitting region ES of the display device 1 according to the present embodiment.

As described above, the display device 1 according to the present embodiment includes the bank 32 provided with the opening 32a including the opening sidewall 32al that is inclined (specifically the opening sidewall 32a1 provided with the inclined face having a tapered shape), the second electrode 33 formed on the bank 32, closing the opening 32a, the third electrode 36 formed above the second electrode 33, and the EL layer 35 including at least the ELM 353 and formed between the second electrode 33 and the third electrode 36, adjacently to the second electrode 33 and the third electrode 36. The second electrode 33 is provided with an inclined face formed on the opening sidewall 32a1 along the opening sidewall 32a1. The EL layer 35 is provided with an inclined face formed on the inclined face of the second electrode 33 along the inclined face of the second electrode 33. The third electrode 36 is provided with an inclined face formed on the inclined face of the EL layer 35 along the inclined face of the EL layer 35.

In such a display device 1, when a current equal to or greater than a light emission threshold current is supplied between the second electrode 33 and the third electrode 36, the EML 353 therebetween emits light. Of the light emitted from the EML 353, light incident on the interface between the second electrode 33 and the third electrode 36 at an angle (incident angle) smaller than a total reflection angle (critical angle) is emitted to the outside in a light extraction direction (front direction) of the display device 1 via the third electrode 36, the high-refractive-index material layer 37, and the low-refractive-index material layer 38.

On the other hand, of the light emitted from the EML 353, the light incident on the interface between the second electrode 33 and the third electrode 36 at an angle (incident angle) equal to or larger than the total reflection angle (critical angle) is totally reflected at the interface. The light totally reflected at the interface between the second electrode 33 and the third electrode 36 propagates inside the EL layer 35 in the in-plane direction thereof while being reflected at the interface between the second electrode 33 and the EL layer 35 and the interface between the third electrode 36 and the EL layer 35 in the opening 32a of the bank 32. Then, when this light propagating inside the EL layer 35 reaches the inclined face of the second electrode 33 formed on the opening sidewall 32al of the opening 32a, the light is reflected by the inclined face and is emitted to the outside in the light extraction direction (front direction) of the display device 1 via the third electrode 36, the high-refractive-index material layer 37, and the low-refractive-index material layer 38.

According to the present embodiment, the second electrode 33 formed on the opening sidewall 32al of the opening 32a functions as a reflective layer and also functions as an electrode. Therefore, the light (guided light component) propagating (guided) by total reflection in the EL layer 35 toward the opening sidewall 32a1 described above can be reflected by the second electrode 33 as the reflective layer (in other words, the inclined face of the second electrode 33 that is a reflective surface) provided on the opening sidewall 32a1 and extracted to the outside in a light extraction direction (front direction) of the display device 1. Further, according to the present embodiment, the second electrode 33 itself formed on the opening sidewall 32a1 of the opening 32a also functions as an electrode, making it possible for the EML 353 to emit light on the opening sidewall 32a1 as well, as illustrated in FIG. 8. Therefore, the opening sidewall 32al of the bank 32 can also be utilized as a light-emitting portion, and the light-emitting area can be increased and the light extraction efficiency can be improved as compared with a case in which an electrode capable of supplying current to the EL layer 35 is not formed on the opening sidewall 32a1 of the bank 32.

In addition, according to the present embodiment, the second electrode 33 itself formed on the opening sidewall 32a1 of the opening 32a described above also functions as an electrode, making it possible to increase the electrode area. This makes it possible to suppress a rise in the drive voltage caused by the opening 32a of the bank 32 having the small hole shape described above.

Accordingly, according to the present embodiment, it is possible to provide a light-emitting device more capable of improving a light extraction efficiency and suppressing a rise in drive voltage than ever before.

Further, according to the present embodiment, the opening 32a of the bank 32 has the small hole shape described above, in particular, the inclination angle (θ) described above, the opening size (φ1) on the upper side of the bank 32 described above, the opening size on the lower side of the bank 32 described above, the height (h) of the bank 32 described above, and the like, making it possible to efficiently extract the guided light component to the outside.

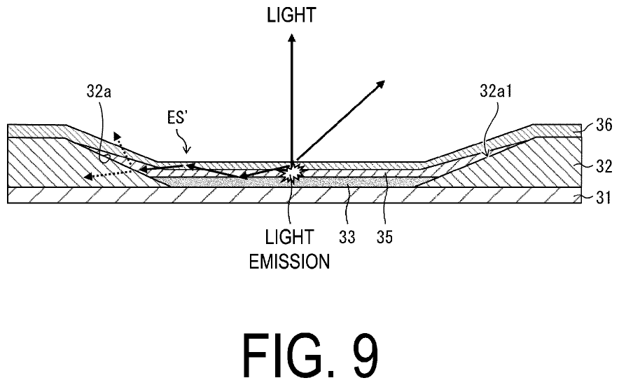

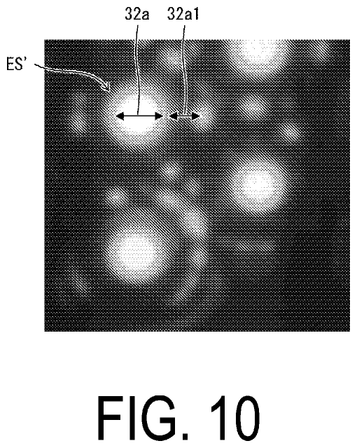

On the other hand, FIG. 9 is a cross-sectional view illustrating an optical path of light in a light-emitting region ES' of a comparative light-emitting element in which the second electrode 33 is not formed on the opening sidewall 32a1 of the bank 32. Further, FIG. 10 is a diagram illustrating an optical microscope photograph showing a light emission state in the light-emitting region ES' of the comparative light-emitting element illustrated in FIG. 9.

As illustrated in FIG. 9, in a case in which the second electrode 33 is not formed on the opening sidewall 32al of the opening 32a, it is not possible to efficiently extract, in the front direction of the display device 1, the light (guided light component) of the light emitted from the EML 353 propagating (guided) toward the opening sidewall 32al inside the EL layer 35 by total reflection.

According to the present embodiment, as described above, the guided light component can be reflected by the inclined face of the second electrode 33 and extracted in the front direction, and the inclined face itself of the second electrode 33 functions as a light-emitting portion. On the other hand, in the structure illustrated in FIG. 9, light that is guided and cannot be extracted in the front direction is incident on the opening sidewall 32a1 of the bank 32 and thus can be extracted only slightly. Therefore, even if the guided light component can be reflected by the inclined face of the second electrode 33 and extracted in the front direction as shown in FIG. 10 only by forming the opening 32a of the bank 32 into the small hole shape described above as illustrated in FIG. 9, the light extraction efficiency on the opening sidewall 32al is low compared to that of the display device 1 according to the present embodiment, and sufficient brightness cannot be obtained. Note that, needless to say, a high current density is required to obtain the same level of brightness as that of the first embodiment in the structure illustrated in FIG. 9, and a rise in drive voltage cannot be suppressed.

Further, as described above, the lower electrode layer on the sidewall of the bank of the light-emitting device described in PTL 1 is covered with the insulating film, and therefore is merely a reflective layer that does not function as an electrode, and a light-emitting portion is not provided on the sidewall of the bank. Further, the light-emitting device described in PTL 1 is only provided with a plurality of banks in a striped pattern at an inclination angle from 400 to 50°, and there is no description regarding bank size. As described above, in the light-emitting device described in PTL 1, the concern arises that the guided light component cannot be efficiently extracted when a distance between adjacent banks is long, yet the drive voltage rises when the distance between adjacent banks is short.

Accordingly, according to the present embodiment, as described above, it is possible to provide a light-emitting device more capable of improving a light extraction efficiency and suppressing an increase in drive voltage than ever before.

### Second Embodiment

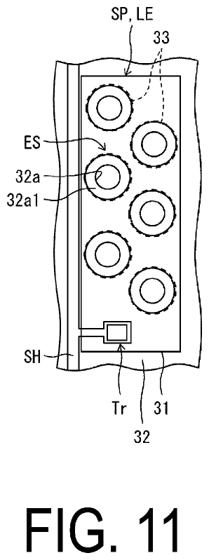

A description of another embodiment of the disclosure will be described as follows mainly with reference to FIG. 11. Note that, for convenience of description, members having the same functions as those of the members described in the previous embodiment will be denoted by the same reference numerals and signs, and descriptions thereof will not be repeated.

FIG. 11 is a plan view illustrating an example of a schematic configuration of the main portions of the display device 1 according to the present embodiment, as viewed from above the second electrode 33 of each subpixel SP of the display device 1.

In the display device 1 according to the present embodiment, a plurality of the second electrodes 33 are provided in each subpixel SP by being formed into island shapes for each light-emitting region ES (in other words, for each opening 32a) as illustrated in FIG. 11, for example, overlapping a portion of the first electrode 31 in each subpixel SP. The display device 1 according to the present embodiment is the same as the display device 1 according to the first embodiment except for this point.

The second electrode 33 according to the present embodiment is patterned and thus formed only in the opening 32a of the bank 32 including the opening sidewall 32al provided with the inclined face, for example.

In the present embodiment, an edge of each second electrode 33 is positioned on the upper face of the bank 32. The edge cover 34 is formed on the bank 32, covering the upper face of the bank 32 and the edge of each second electrode 33.

According to the present embodiment, the second electrode 33 is formed into an island shape for each light-emitting region ES, more preferably, the second electrode 33 is patterned only in the openings 32a of the bank 32 including the opening sidewalls 32al provided with the inclined faces, and a transparent electrode is used as the first electrode 31, making it possible to suppress unnecessary reflection of the display device 1.

### Third Embodiment

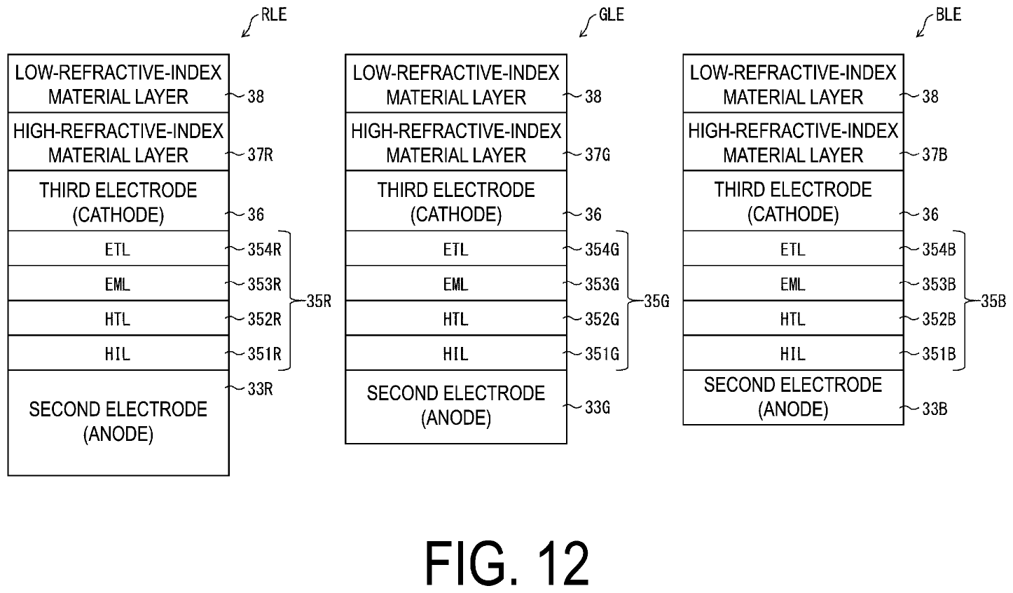

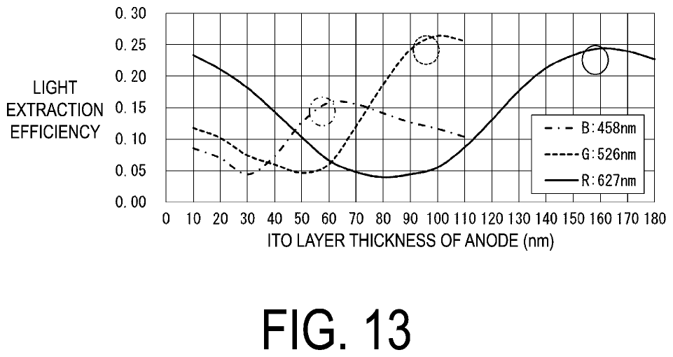

A description of yet another embodiment of the disclosure will be described as follows mainly with reference to FIG. 12 and FIG. 13. Note that, for convenience of description, members having the same functions as those of the members described in the previous embodiment will be denoted by the same reference numerals and signs, and descriptions thereof will not be repeated.

FIG. 12 is a view schematically illustrating an example of a layered structure in each light-emitting region (light-emitting region RES, light-emitting region GES, and light-emitting region BES) of the light-emitting element LE (light-emitting element RLE, light-emitting element GLE, and light-emitting element BLE) of each color of the display device 1 according to the present embodiment. Note that FIG. 12 also illustrates, as an example, a case in which the display device 1 is a top-emission display device having a conventional structure, but the display device 1 according to the present embodiment is not limited thereto.

The display device 1 according to the present embodiment is the same as the display device 1 according to the first and second embodiments except that the anode film thicknesses of the optical distance adjustment layers in each subpixel SP differ. Specifically, in the present embodiment, as in the first embodiment, the second electrode 33 is formed of a layered body obtained by layering an Ag alloy including Ag and ITO in the order of ITO/Ag alloy/ITO from the lower layer side. In the present embodiment, a layer thickness of the ITO (light-transmissive electrode) on the Ag alloy (reflective electrode) of the second electrode 33 is changed for each subpixel SP (in other words, for each light-emitting element LE).

The effect of the microcavity structure applied in the OLED can be obtained by optimally designing the layer thicknesses of the layers between the anode reflective electrode and the cathode translucent electrode or the like. However, the layer thickness of an EL layer (HTL, for example) or the like other than the light-emitting layer also needs to be changed in accordance with the luminescent color of the OLED. Further, there is a possibility that the carrier balance changes due to a change in the layer thickness of each EL layer, making the optimized design overly complex.

On the other hand, when the anode film thickness of the QLED is designed with the light extraction efficiency optimized in accordance with the luminescent color of the QLED as in the present embodiment, the carrier balance in the QLED does not change. Therefore, in this case, the light extraction efficiency can be improved by a layer structure (layer thickness of each EL layer) with an optimized carrier balance.

In the example illustrated in FIG. 12, in the top-emission display device 1 having a conventional structure, the second electrode 33 of the light-emitting element LE of each color of the subpixel SP of each color, which is the anode, has a layered structure of a reflective electrode and a light-transmissive electrode. Then, the figure illustrates, as an example, a case in which the layer thickness of the light-transmissive electrode of the second electrode 33 of each light-emitting element LE is changed for each subpixel SP (in other words, for each light-emitting element LE of each color) in order to maximize the light extraction efficiency in each light-emitting region ES of the light-emitting element LE of each subpixel SP.

As illustrated in FIG. 12, the light-emitting element RLE includes, for example, the second electrode 33R, the EL layer 35R, the third electrode 36, the high-refractive-index material layer 37R, and the low-refractive-index material layer 38 in this order from the lower layer side in each of the light-emitting regions RES. The EL layer 35R includes, for example, the HIL 351R, the HTL 352R, the EML 353R, and the ETL 354R in this order from the lower layer side.

Further, the light-emitting element GLE includes, for example, the second electrode 33G, the EL layer 35G, the third electrode 36, the high-refractive-index material layer 37G, and the low-refractive-index material layer 38 in this order from the lower layer side in each of the light-emitting regions GES. The EL layer 35G includes, for example, the HIL 351G, the HTL 352G, the EML 353G, and the ETL 354G in this order from the lower layer side.

The light-emitting element BLE includes, for example, the second electrode 33B, the EL layer 35B, the third electrode 36, the high-refractive-index material layer 37B, and the low-refractive-index material layer 38 in this order from the lower layer side in each of the light-emitting regions BES. The EL layer 35B includes, for example, the HIL 351B, the HTL 352B, the EML 353B, and the ETL 354B in this order from the lower layer side.

FIG. 13 is a graph showing a relationship between a layer thickness of ITO on the reflective electrode and a light extraction efficiency in each anode (that is, second electrode 33R, second electrode 33G, and second electrode 33B) in each light-emitting region ES of the light-emitting elements LE of each color.

In the present embodiment, the layer thickness of the light-transmissive electrode (ITO) on the reflective electrode of the anode of the light-emitting element LE of each color is selected with reference to the result of an optical simulation shown in FIG. 13. At this time, as the layer thickness of the light-transmissive electrode (ITO), a desired layer thickness was selected such that the light extraction efficiency in each light-emitting region ES of the light-emitting element LE of each color was maximized.

In the layered structure in the simulation, the PEDOT:PSS for the HIL 351R, the HIL 351G, and the HIL 351B was set at a layer thickness of 40 nm. For the HTL 352R, the HTL 352G and the HTL 352B, the TFB was set at a layer thickness of 35 nm. In the EML 353R, the red QDs were set at a layer thickness of 30 nm. In the EML 353G, the green QDs were set at a layer thickness of 30 nm. In the EML 353B, the blue QDs were set at a layer thickness of 30 nm. For the ETL 354R, the ETL 354G, and the ETL 354B, ZnO was set at a layer thickness of 50 nm. The third electrode 36 was formed of ITO at a layer thickness of 100 nm.

Note that, in this simulation, to simplify calculation, the bank structure was not set, and the high-refractive-index material and the low-refractive-index material were omitted.

From the results shown in FIG. 13, in the present embodiment, the layer thicknesses of the light-transmissive electrodes on the reflective electrodes of the second electrodes 33 were set with the thickness of the light-transmissive electrode on the second electrode 33R being greater than the thickness of the light-transmissive electrode on the second electrode 33G which was greater than the thickness of the light-transmissive electrode on the second electrode 33B.

Specifically, as described above, the second electrode 33 had a layered structure (three-layer structure) of ITO/Ag/ITO. Then, in the light-emitting region RES of the subpixel RSP, the layer thickness of the ITO positioned on the Ag electrode of the reflective electrode in the second electrode 33R (that is, layer thickness of the ITO positioned between the reflective electrode of the second electrode 33R and the third electrode 36) was set to 160 nm.

In the light-emitting region GES of the subpixel GSP, the layer thickness of the ITO positioned on the Ag electrode of the reflective electrode in the second electrode 33G (that is, layer thickness of the ITO positioned between the reflective electrode of the second electrode 33G and the third electrode 36) was set to 100 nm.

In the light-emitting region BES of the subpixel BSP, the layer thickness of the ITO positioned on the Ag electrode of the reflective electrode in the second electrode 33B (that is, layer thickness of the ITO positioned between the reflective electrode of the second electrode 33B and the third electrode 36) was set to 65 nm.

Further, from the HIL 351 to the ITO of the third electrode 36, the layers were formed at the same layer thickness using the same materials as those in the simulation. Specifically, PEDOT:PSS was formed for the HIL 351R, the HIL 351G, and the HIL 351B at a layer thickness of the 40 nm. TFB was formed for the HTL 352R, the HTL 352G, and the HTL 352B at a layer thickness of 35 nm. In the EML 353R, red QDs were formed at a layer thickness of 30 nm. In the EML 353G, green QDs were formed at a layer thickness of 30 nm. In the EML 353B, blue QDs were formed at a layer thickness of 30 nm. For the ETL 354R, the ETL 354G, and the ETL 354B, ZnO was formed at a layer thickness of 50 nm. The third electrode 36 was formed of ITO at a layer thickness of 100 nm. The high-refractive-index material layer 37 was formed at a layer thickness of 2 μm on the lower ends of the openings 32a of the bank 32, filling the recesses (trench portions) of the third electrode 36 in the formation region of the bank 32. The low-refractive-index material layer 38 was formed at a layer thickness (design value) of 350 nm.

According to the present embodiment, the layer thickness of the light-transmissive electrode of the second electrode 33R, the layer thickness of the light-transmissive electrode of the second electrode 33G, and the layer thickness of the light-transmissive electrode of the second electrode 33B were set as described above, making it possible to improve the light extraction efficiencies of the light-emitting region RES, the light-emitting region GES, and the light-emitting region BES.

Note that, in the present embodiment, a case in which the layer thicknesses of the light-transmissive electrodes on the reflective electrode of the second electrodes 33 differ from one another in the subpixel RSP, the subpixel GSP, and the subpixel BSP has been described as an example. In the present embodiment, as described above, the layer thicknesses of the light-transmissive electrodes decrease in the order of the layer thickness of the light-transmissive electrode of the second electrode 33R, the layer thickness of the light-transmissive electrode of the second electrode 33G, and the layer thickness of the light-transmissive electrode of the second electrode 33B. However, if the device structure is changed, the thickness relationship is not limited thereto. Depending on the device structure, the relationship between layer thicknesses of the light-transmissive electrodes may vary.

For example, the layer thickness of the light-transmissive electrode in one subpixel SP of the subpixel RSP, the subpixel GSP, and the subpixel BSP may differ from the layer thickness of the light-transmissive electrodes in the remaining two subpixels SP.

Accordingly, in the second electrodes 33, the layer thicknesses of the light-transmissive electrodes described above may differ from each other in at least two subpixels SP among the subpixel RSP, the subpixel GSP, and the subpixel BSP. That is, when the layer thicknesses of the light-transmissive electrodes on the reflective electrodes of the second electrodes 33 are compared between at least two selected subpixels SP, the layer thicknesses of the light-transmissive electrodes may differ from each other. In other words, the layer thickness of the light-transmissive electrode of at least one subpixel SP of the subpixel RSP, the subpixel GSP, and the subpixel BSP may differ from the layer thickness of the light-transmissive electrodes of the other subpixels SP.

### Fourth Embodiment

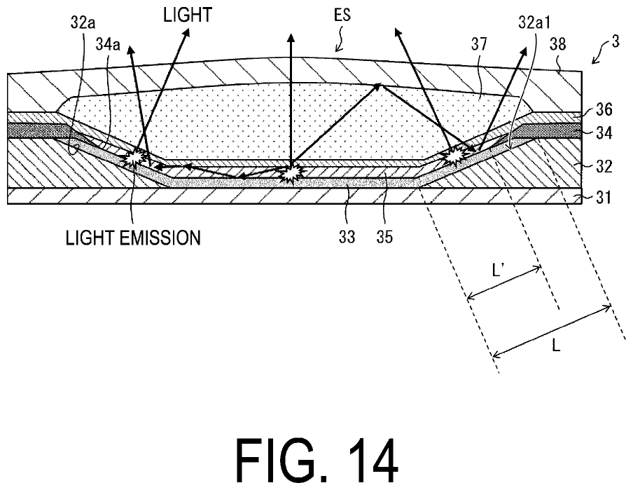

A description of yet another embodiment of the disclosure will be described as follows mainly with reference to FIG. 14. Note that, for convenience of description, members having the same functions as those of the members described in the previous embodiment will be denoted by the same reference numerals and signs, and descriptions thereof will not be repeated.

FIG. 14 is a cross-sectional view illustrating a schematic configuration of main portions of the light-emitting element layer 3 of the display device 1 according to the present embodiment, together with an optical path of light in the light-emitting region ES in the light-emitting element layer 3.

In the present embodiment, for example, as illustrated in FIG. 14, the second electrode 33 is patterned, forming the second electrode 33 only in the opening 32a of the bank 32 including the opening sidewall 32a1 provided with an inclined face, and forming an end portion (opening end) of the opening 34a of the edge cover 34 on the opening sidewall 32a1.

As a result, in the present embodiment, only the portion of the second electrode 33 on the opening sidewall 32a1 of the bank 32 not covered with the edge cover 34 functions as a light-emitting portion on the opening sidewall 32al.

In the present embodiment, a portion of the second electrode 33 on the opening sidewall 32a1 (that is, a portion of the inclined face of the second electrode 33) is covered with the edge cover 34. Therefore, the EL layer 35 is provided with an inclined face in a portion of the opening sidewall 32al along a portion of the inclined face of the second electrode 33 (that is, a portion of the inclined face of the second electrode 33 not covered with the edge cover 34). Further, the third electrode 36 is provided with an inclined face in a portion on the opening sidewall 32al along the inclined face of the EL layer 35 along the inclined face of the second electrode 33.

The display device 1 according to the present embodiment is the same as the display device 1 according to the first to third embodiments except for these points.

In the present embodiment, given L as a length of the opening sidewall 32al of the bank 32 and L′ as a length of a portion of the opening sidewall 32al not covered with the edge cover 34, the edge cover 34 is patterned by, for example, photolithography, positioning the end portion of the opening 34a of the edge cover 34 at a position where the L′ is longer than ⅓L and shorter than ⅔L. That is, in the present embodiment, the edge cover 34 is formed to satisfy ⅓L<L′<⅔L.

Note that the length (L) of the opening sidewall 32al of the bank 32 indicates a length connecting the upper end and the lower end of the opening sidewall 32al of the bank 32 at the shortest distance along the surface of the opening sidewall 32al. Further, the lower end of the opening sidewall 32al of the bank 32 refers to an end portion of the opening 34a of the bank 32 on the first electrode 31 side (lower side that is the array substrate 2 side). An upper end of the opening sidewall 32al of the bank 32 refers to an end portion of the opening 34a of the bank 32 on the side opposite to the first electrode 31 side (upper side that is the sealing layer 4 side).

Further, the length (L′) of the portion of the opening sidewall 32al of the bank 32 not covered with the edge cover 34 is, among the lengths connecting the upper end and the lower end of the opening sidewall 32al of the bank 32 at the shortest distance along the surface of the opening sidewall 32al, the length that connects the end portion of the opening 34a of the edge cover 34 positioned on the opening sidewall 32al of the bank 32 and the lower end of the opening sidewall 32al of the bank 32 at the shortest distance along the surface of the opening sidewall 32al. Note that the length (L′) of the portion of the opening sidewall 32al of the bank 32 not covered with the edge cover 34 can be rephrased as the length of the portion on the opening sidewall 32al where the second electrode 33 functions as an electrode (inclined face electrode).

According to the present embodiment, by forming the edge cover 34 in this way, it is possible to suppress leakage (that is, anode-cathode leakage) between the second electrode 33 and the third electrode 36 due to thinning of the EL layer 35 formed on the inclined face of the opening sidewall 32al. Further, it is possible to cause the light-emitting portion (inclined face light-emitting portion) of the opening sidewall 32al to effectively function.

Note that FIG. 14 illustrates, as an example, a case in which the second electrode 33 is patterned, forming the second electrodes 33 only in the openings 32a of the bank 32, including the opening sidewalls 32al provided with the inclined faces, as described above.

However, the present embodiment is not limited to this example. As long as the edge cover 34 is formed as described above, the second electrode 33 may be formed into an island shape for each subpixel SP as illustrated in the first embodiment. In this case as well, similar advantageous effects to those described above can be obtained.

### Fifth Embodiment

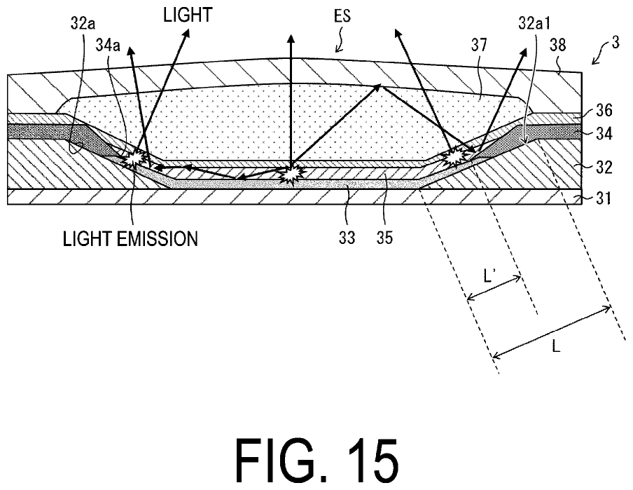

A description of yet another embodiment of the disclosure will be described as follows mainly with reference to FIG. 15. Note that, for convenience of description, members having the same functions as those of the members described in the previous embodiment will be denoted by the same reference numerals and signs, and descriptions thereof will not be repeated.

FIG. 15 is a cross-sectional view illustrating a schematic configuration of the light-emitting element layer 3 of the display device 1 according to the present embodiment, together with an optical path of light in the light-emitting region ES in the light-emitting element layer 3.

In the present embodiment, as illustrated in FIG. 15, the second electrode 33 is patterned, positioning an edge of the second electrode 33 in the middle of the opening sidewall 32al (that is, in the middle of the inclined face of the opening sidewall 32al), and the end portion (opening end) of the opening 34a of the edge cover 34 is formed on the opening sidewall 32al, covering the edge of the second electrode 33. Note that the middle of the opening sidewall 32al refers to a portion between the upper end and the lower end of the opening sidewall 32a1.

As a result, in the present embodiment, only the portion on the opening sidewall 32a1 of the bank 32 that is where the second electrode 33 is formed and is not covered by the edge cover 34 functions as the light-emitting portion on the opening sidewall 32a1.

Further, in the present embodiment, as described above, the second electrode 33 covers a portion of the opening sidewall 32al, and the edge cover 34 covers the edge of the second electrode 33 and the portion of the opening sidewalls 32a1 not covered with the second electrode 33. As a result, the second electrode 33 is provided with an inclined face along the inclined face of the opening sidewall 32a1 in a portion on the opening sidewall 32a1. Therefore, the EL layer 35 is provided with an inclined face along the inclined face of the second electrode 33 in a portion on the opening sidewall 32a1. Therefore, the third electrode 36 is provided with an inclined face along the inclined face of the second electrode 33 in a portion on the opening sidewall 32a1.

The display device 1 according to the present embodiment is the same as the display device 1 according to the first to fourth embodiments except for these points.

In the present embodiment as well, given L as the length of the opening sidewall 32al of the bank 32 and L′ as the length of the portion of the opening sidewall 32al not covered with the edge cover 34, the second electrode 33 and the edge cover 34 are patterned by, for example, photolithography, positioning the end portion of the opening 34a of the edge cover 34 at a position where the L′ is longer than ⅓L and shorter than ⅔L. That is, in the present embodiment, the edge cover 34 is formed satisfying ⅓L<L′ <⅔L, and the second electrode 33 is patterned in the opening 32a of the bank 32, covering the edge of the second electrode 33 with the edge cover 34. Note that, in the present embodiment as well, similarly to the fourth embodiment, the length (L′) of the portion of the opening sidewall 32a1 of the bank 32 not covered with the edge cover 34 can be rephrased as the length of the portion on the opening sidewall 32a1 where the second electrode 33 functions as an electrode (inclined face electrode).

According to the present embodiment as well, by forming the edge cover 34 as described above, it is possible to suppress leakage (that is, anode-cathode leakage) between the second electrode 33 and the third electrode 36 due to thinning of the EL layer 35 formed on the inclined face of the opening sidewall 32a1. Further, it is possible to cause the light-emitting portion (inclined face light-emitting portion) of the opening sidewall 32al to effectively function.

Further, according to the present embodiment, in an upper layer overlying the bank 32, the reflective layer in portions other than the opening 32a of the bank 32 is made as small as possible, making it possible to suppress unnecessary reflection.

### First Modified Example

Note that, in the first to fifth embodiments described above, description is made using, as an example, a case in which the light-emitting device according to the disclosure is a display device. However, the light-emitting device according to the disclosure is not limited thereto and may be, for example, an illumination device or may be a light-emitting element.

### Second Modified Example

Further, in FIG. 2, FIG. 8, and FIG. 11, description is made using, as an example, a case in which the bank 32 includes the plurality of openings 32a in each subpixel SP. However, the configuration of the light-emitting device (display device 1, for example) according to the disclosure is not limited to the configuration described above. The bank 32 need only include at least one through-hole (opening 32a, for example) in each subpixel SP. Therefore, depending on the relationship between the size of the subpixel SP and the size of the through-hole (opening 32a, for example), only one through-hole (opening 32a, for example) need be formed in each subpixel SP.

Further, in the first to fifth embodiments described above, description is made using, as an example, a case in which the opening 32a has the small hole shape described above. However, although desirably the opening 32a has the small hole shape described above, the opening 32a is not limited thereto and needs only to include the opening sidewall 32a1 that is inclined.

### REFERENCE SIGNS LIST

1 Display device (light-emitting device)
2 Array substrate
31 First electrode (connection electrode)
32 Bank
32a, 34a Opening
32al Opening sidewall
33, 33B, 33G, 33R Second electrode (lower layer electrode)
34 Edge cover
35, 35B, 35G, 35R EL layer
36 Third electrode (upper layer electrode)
37, 37B, 37G, 37R High-refractive-index material layer (first refractive index layer)
38 Low-refractive-index material layer (second refractive index layer)
LE Light-emitting element (light-emitting device)

1. A light-emitting device comprising:
a bank provided with a through-hole including an opening sidewall, the opening sidewall being inclined;
a lower layer electrode formed on the bank, closing the through-hole;
an upper layer electrode formed above the lower layer electrode; and
an EL layer formed between the lower layer electrode and the upper layer electrode, adjacently to the lower layer electrode and the upper layer electrode,
wherein the lower layer electrode is provided with an inclined face along at least a portion of the opening sidewall,
the EL layer includes at least a light-emitting layer and is provided with an inclined face along at least a portion of the inclined face of the lower layer electrode, and
the upper layer electrode is provided with an inclined face along at least a portion of the inclined face of the EL layer, and
further comprising:
a first refractive index layer having a refractive index higher than 1.7; and
a second refractive index layer having a refractive index lower than the refractive index of the first refractive index layer,
wherein the first refractive index layer and the second refractive index layer are formed in this order on the upper layer electrode at the through-hole.

2. The light-emitting device according to claim 1,
wherein an angle formed by a lower face of the bank and the opening sidewall is equal to or greater than 200 and equal to or less than 30°.

3. (canceled)

4. The light-emitting device according to claim 1,
wherein an aperture diameter of the through-hole on a lower end side is equal to or greater than 10 μm and equal to or less than 20 μm.

5. The light-emitting device according to claim 1,
wherein a height between an upper end and a lower end of the through-hole is equal to or greater than 1 μm and equal to or less than 4 μm.

6. The light-emitting device according to claim 1,
wherein the light-emitting layer is a quantum dot light-emitting layer including a quantum dot.

7. The light-emitting device according to claim 1, comprising:
a plurality of subpixels,
wherein the light-emitting device is a display device, and
the bank includes at least one of the through-holes in each subpixel of the plurality of subpixels.

8. The light-emitting device according to claim 7,
wherein the bank includes a plurality of the through-holes, each having a small hole shape, as the at least one through-hole in each subpixel of the plurality of subpixels.

9. The light-emitting device according to claim 7, further comprising:
an array substrate including a plurality of thin film transistors; and
a plurality of connection electrodes each formed on the array substrate for a corresponding one of the plurality of subpixels and connected to a corresponding one of the plurality of thin film transistors,
wherein the bank is formed on the array substrate, covering the plurality of connection electrodes with the at least one through-hole exposing a portion of the plurality of connection electrodes, and
the lower layer electrode is connected to the plurality of connection electrodes at the at least one through-hole.

10. The light-emitting device according to claim 7,
wherein the plurality of subpixels include a red subpixel, a green subpixel, and a blue subpixel,
the lower layer electrode includes at least a reflective electrode and a light-transmissive electrode formed on the reflective electrode, and
in at least two subpixels of the red subpixel, the green subpixel, and the blue subpixel, layer thicknesses of the light-transmissive electrodes differ from each other.

11. The light-emitting device according to claim 7,
wherein the lower layer electrode is formed into an island shape for each of the plurality of subpixels.

12. The light-emitting device according to claim 11, further comprising:
an edge cover on the bank, the edge cover including a through-hole corresponding to the at least one through-hole of the bank, opening the at least one through-hole of the bank,
wherein the edge cover covers a portion of the lower layer electrode positioned on an upper face of the bank.

13. The light-emitting device according to claim 7,
wherein the lower layer electrode is formed into an island shape for each of the at least one through-hole.

14. The light-emitting device according to claim 1,
wherein the light-emitting device is a light-emitting element.

15. The light-emitting device according to claim 1, wherein the lower layer electrode is formed only in the at least one through-hole.

16. The light-emitting device according to claim 15,
wherein the lower layer electrode is formed with an edge of the lower layer electrode positioned between an upper end and a lower end of the opening sidewall.

17. The light-emitting device according to claim 16, further comprising:
an edge cover on the bank, the edge cover including a through-hole with an opening end on the opening sidewall of the bank,
wherein ⅓L<L′<⅔L, where L is a length of the opening sidewall of the bank and L′ is a length of a portion of the opening sidewall not covered with the edge cover.

18. A light-emitting device comprising:
a bank provided with a through-hole including an opening sidewall, the opening sidewall being inclined;
a lower layer electrode formed on the bank, closing the through-hole;
an upper layer electrode formed above the lower layer electrode; and
an EL layer formed between the lower layer electrode and the upper layer electrode, adjacently to the lower layer electrode and the upper layer electrode,
wherein the lower layer electrode is provided with an inclined face along at least a portion of the opening sidewall,
the EL layer includes at least a light-emitting layer and is provided with an inclined face along at least a portion of the inclined face of the lower layer electrode,
the upper layer electrode is provided with an inclined face along at least a portion of the inclined face of the EL layer, and
an angle formed by a lower face of the bank and the opening sidewall is equal to or greater than 20° and equal to or less than 30°.
